(19) United States
(12) Patent Application Publication
(10) Pub. No.: US 2025/0112618 A1
(43) Pub. Date: Apr. 3, 2025

(54) ACOUSTIC WAVE DEVICE

(71) Applicant: Murata Manufacturing Co., Ltd., Nagaokakyo-shi (JP)

(72) Inventors: Naohiro NODAKE, Nagaokakyo-shi (JP); Sho NAGATOMO, Nagaokakyo-shi (JP); Masakazu MIMURA, Nagaokakyo-shi (JP)

(21) Appl. No.: 18/980,079

(22) Filed: Dec. 13, 2024

Related U.S. Application Data
(63) Continuation of application No. PCT/JP2023/028485, filed on Aug. 3, 2023.
(60) Provisional application No. 63/394,719, filed on Aug. 3, 2022.

(51) Int. Cl. H03H 9/13; H03H 9/02; H03H 9/05; H03H 9/10; H03H 9/17

(52) U.S. Cl. CPC H03H 9/132; H03H 9/02031; H03H 9/02157; H03H 9/02228; H03H 9/0523; H03H 9/105; H03H 9/173; H03H 9/175; H03H 9/176

(57) ABSTRACT

An acoustic wave device includes a piezoelectric substrate including a piezoelectric layer with first and second main surfaces, and a support on the second main surface, a first comb-shaped electrode on the first main surface including a first busbar and first electrode fingers connected to the first busbar and being connected to an input potential, a second comb-shaped electrode on the first main surface including a second busbar and second electrode fingers connected to the second busbar and interdigitated with the first electrode fingers, and connected to an output potential, and a reference potential electrode connected to a reference potential and including third electrode fingers on the first main surface and aligned with the first and second electrode fingers, connection electrodes connected to the third electrode fingers, respectively, and a third busbar electrically connected to the third electrode fingers by the connection electrodes.

### CROSS REFERENCE TO RELATED APPLICATIONS

This application claims the benefit of priority to Provisional Application No. 63/394,719 filed on Aug. 3, 2022 and is a Continuation of Application PCT Application No. PCT/JP2023/028485 filed on Aug. 3, 2023. The entire contents of each application are hereby incorporated herein by reference.

### BACKGROUND OF THE INVENTION

### 1. Field of the Invention

The present invention relates to acoustic wave devices.

### 2. Description of the Related Art

Acoustic wave devices have heretofore been widely used in filters for mobile phones and the like. An acoustic wave device using bulk waves in a thickness-shear mode has recently been proposed, as described in U.S. Pat. No. 10, 491, 192. In this acoustic wave device, a piezoelectric layer is provided on a support. A pair of electrodes are provided on the piezoelectric layer. The pair of electrodes face each other on the piezoelectric layer and are connected to different potentials. An AC voltage is applied between the electrodes to excite bulk waves in the thickness-shear mode.

### SUMMARY OF THE INVENTION

An acoustic wave device is, for example, an acoustic wave resonator, and is used in a ladder filter, for example. In order to obtain good characteristics in the ladder filter, the electrostatic capacity ratio needs to be increased between a plurality of acoustic wave resonators. In this case, the electrostatic capacities of some of the acoustic wave resonators in the ladder filter need to be increased.

In order to increase the electrostatic capacity of the acoustic wave resonator, the acoustic wave resonator needs to be increased in size. For this reason, in the case of using such an acoustic wave resonator in a ladder filter, the ladder filter tends to be increased in size. In particular, a ladder filter including an acoustic wave resonator that uses a thickness-shear mode bulk wave with a small electrostatic capacity tends to be increased in size.

The inventors of example embodiments of the present invention have discovered that when an acoustic wave device is used in a filter device, using the following configuration of the acoustic wave device can obtain a suitable filter waveform without increasing the size. In this configuration, an electrode connected to a reference potential is disposed between an electrode connected to an input potential and an electrode connected to an output potential.

However, the inventors of example embodiments of the present invention have also discovered that the above configuration has a large layout constraint on the electrode connected to the reference potential, and that the width of the electrode tends to become narrower and the routing length of the electrode tends to become longer. In this case, the electric resistance of the electrode connected to the reference potential easily increases, and the potential of the electrode easily becomes unstable. Therefore, when the above configuration is used in a filter device, filter characteristics of the filter device may deteriorate.

Example embodiments of the present invention provide acoustic wave devices each capable of promoting miniaturization of a filter device and lowering electric resistance of wiring connected to a reference potential.

An acoustic wave device according to an example embodiment of the present invention includes a piezoelectric substrate including a piezoelectric layer including a first main surface and a second main surface that face each other, and a support laminated on the second main surface of the piezoelectric layer, a first comb-shaped electrode that is provided on the first main surface of the piezoelectric layer, includes a first busbar and a plurality of first electrode fingers each including one end connected to the first busbar, and is connected to an input potential, a second comb-shaped electrode that is provided on the first main surface of the piezoelectric layer, includes a second busbar and a plurality of second electrode fingers each including one end connected to the second busbar and interdigitated with the plurality of first electrode fingers, and is connected to an output potential; and a reference potential electrode that is connected to a reference potential and includes a plurality of third electrode fingers provided on the first main surface of the piezoelectric layer so as to be aligned with the first electrode fingers and the second electrode fingers in a direction in which the first electrode fingers and the second electrode fingers are arranged, a plurality of connection electrodes connected to the plurality of third electrode fingers, respectively, and a third busbar electrically connected to the plurality of third electrode fingers by the plurality of connection electrodes, in which an order in which the first electrode finger, the second electrode finger, and the third electrode finger are arranged is such that, starting from the first electrode finger, the first electrode finger, the third electrode finger, the second electrode finger, and the third electrode finger define one period, and the third busbar faces the plurality of third electrode fingers across at least the piezoelectric layer, and the plurality of connection electrodes penetrate at least the piezoelectric layer to connect the third busbar to the plurality of third electrode fingers.

An acoustic wave device according to another example embodiment of the present invention includes a piezoelectric substrate including a piezoelectric layer including a first main surface and a second main surface that face each other, a first comb-shaped electrode that is provided on the first main surface of the piezoelectric layer, includes a first busbar and a plurality of first electrode fingers each including one end connected to the first busbar, and is connected to an input potential, a second comb-shaped electrode that is provided on the first main surface of the piezoelectric layer, includes a second busbar and a plurality of second electrode fingers each including one end connected to the second busbar and interdigitated with the plurality of first electrode fingers, and is connected to an output potential, a reference potential electrode that is connected to a reference potential and includes a plurality of third electrode fingers provided on the first main surface of the piezoelectric layer so as to be aligned with the first electrode fingers and the second electrode fingers in a direction in which the first electrode fingers and the second electrode fingers are arranged, a plurality of connection electrodes connected to the plurality of third electrode fingers, respectively, and a third busbar electrically connected to the plurality of third electrode fingers by the plurality of connection electrodes, a support provided on the piezoelectric substrate, and a cover that is provided on the support and includes a third main surface located on the piezoelectric substrate side and a fourth main surface facing the third main surface, in which an order in which the first electrode finger, the second electrode finger, and the third electrode finger are arranged is such that, starting from the first electrode finger, the first electrode finger, the third electrode finger, the second electrode finger, and the third electrode finger define one period, and the third busbar is provided on the third main surface of the cover so as to face the plurality of third electrode fingers, and the plurality of connection electrodes are provided at least on the plurality of third electrode fingers, and connect the third busbar to the plurality of third electrode fingers.

An acoustic wave device according to yet another example embodiment of the present invention includes a piezoelectric substrate including a piezoelectric layer including a first main surface and a second main surface that face each other, a first comb-shaped electrode that is provided on the first main surface of the piezoelectric layer, includes a first busbar and a plurality of first electrode fingers each including one end connected to the first busbar, and is connected to an input potential, a second comb-shaped electrode that is provided on the first main surface of the piezoelectric layer, includes a second busbar and a plurality of second electrode fingers each including one end connected to the second busbar and interdigitated with the plurality of first electrode fingers, and is connected to an output potential, a reference potential electrode that is connected to a reference potential and includes a plurality of third electrode fingers provided on the first main surface of the piezoelectric layer so as to be aligned with the first electrode fingers and the second electrode fingers in a direction in which the first electrode fingers and the second electrode fingers are arranged, a plurality of connection electrodes connected to the plurality of third electrode fingers, respectively, and a third busbar electrically connected to the plurality of third electrode fingers by the plurality of connection electrodes, a plurality of conductive bonds provided on the piezoelectric substrate, and a mounting substrate that is bonded to the piezoelectric substrate by the plurality of conductive bonds, and includes a fifth main surface located on the piezoelectric substrate side and a sixth main surface facing the fifth main surface, in which an order in which the first electrode finger, the second electrode finger, and the third electrode finger are arranged is such that, starting from the first electrode finger, the first electrode finger, the third electrode finger, the second electrode finger, and the third electrode finger define one period, and the third busbar is provided on the fifth main surface of the mounting substrate so as to face the plurality of third electrode fingers, and the plurality of connection electrodes are provided at least on the plurality of third electrode fingers, and connect the third busbar to the plurality of third electrode fingers.

Example embodiments of the present invention provide acoustic wave devices each capable of promoting miniaturization of a filter device and lowering electric resistance of wiring connected to a reference potential.

The above and other elements, features, steps, characteristics and advantages of the present invention will become more apparent from the following detailed description of the example embodiments with reference to the attached drawings.

### BRIEF DESCRIPTION OF THE DRAWINGS

FIG. 1 is a schematic elevational cross-sectional view of an acoustic wave device according to a first example embodiment of the present invention.

FIG. 2 is a schematic plan view of the acoustic wave device according to the first example embodiment of the present invention.

FIG. 3 is a schematic cross-sectional view taken along line II-II in FIG. 2.

FIG. 4 is a schematic elevational cross-sectional view illustrating the vicinity of first to third electrode fingers in the first example embodiment of the present invention.

FIG. 5 is a graph illustrating bandpass characteristics and reflection characteristics of the acoustic wave device according to the first example embodiment of the present invention.

FIG. 6 is a schematic plan view of an acoustic wave device of a first reference example.

FIG. 7 is a schematic plan view of an acoustic wave device of a second reference example.

FIG. 8 is a schematic elevational cross-sectional view illustrating the vicinity of a portion where a first electrode finger is covered with an insulating film in the second reference example.

FIG. 9 is a diagram illustrating a map of a fractional band width with respect to Euler angles (0°, θ, ψ) of LiNbO₃ when d/p is infinitely close to 0.

FIG. 10 is a schematic cross-sectional view illustrating a portion corresponding to the cross section along line II-II in FIG. 2 in a modification of the first example embodiment of the present invention.

FIG. 11 is a schematic elevational cross-sectional view of an acoustic wave device according to a second example embodiment of the present invention.

FIG. 12 is a schematic elevational cross-sectional view illustrating an enlarged portion of the acoustic wave device according to the second example embodiment of the present invention.

FIG. 13 is a schematic plan view illustrating an electrode configuration on a first main surface of a piezoelectric layer in the second example embodiment of the present invention.

FIG. 14 is a schematic elevational cross-sectional view of an acoustic wave device according to a third example embodiment of the present invention.

FIG. 15 is a schematic elevational cross-sectional view illustrating an enlarged portion of the acoustic wave device according to the third example embodiment of the present invention.

FIG. 16A is a schematic perspective view illustrating an appearance of an acoustic wave device that uses a thickness-shear mode bulk wave, and FIG. 16B is a plan view illustrating an electrode structure on a piezoelectric layer.

FIG. 17 is a cross-sectional view of a portion taken along line A-A in FIG. 16A.

FIG. 18A is a schematic elevational cross-sectional view for explaining a Lamb wave propagating through a piezoelectric film of the acoustic wave device, and FIG. 18B is a schematic elevational cross-sectional view for explaining a thickness-shear mode bulk wave propagating through the piezoelectric film of the acoustic wave device.

FIG. 19 is a diagram illustrating an amplitude direction of the thickness-shear mode bulk wave.

FIG. 20 is a graph illustrating resonance characteristics of the acoustic wave device using the thickness-shear mode bulk wave.

FIG. 21 is a graph illustrating a relationship between d/p and a fractional band width of a resonator, where p is the center-to-center distance between adjacent electrodes and d is the thickness of the piezoelectric layer.

FIG. 22 is a plan view of the acoustic wave device using the thickness-shear mode bulk wave.

FIG. 23 is a diagram illustrating resonance characteristics of the acoustic wave device in a reference example where spurious appears.

FIG. 24 is a diagram illustrating a relationship between a fractional band width and a phase rotation amount of a spurious impedance normalized by 180 degrees as a magnitude of spurious.

FIG. 25 is a diagram illustrating a relationship between d/2p and a metallization ratio MR.

FIG. 26 is a diagram illustrating a map of the fractional band width with respect to Euler angles (0°, θ, ψ) of LiNbO₃ when d/p is infinitely close to 0.

FIG. 27 is an elevational cross-sectional view of an acoustic wave device including an acoustic multilayer film.

FIG. 28 is a partially cutaway perspective view for explaining an acoustic wave device that uses a Lamb wave.

### DETAILED DESCRIPTION OF THE EXAMPLE EMBODIMENTS

The present invention will be clarified below by describing specific example embodiments of the present invention with reference to the drawings.

It should be noted that the example embodiments described in this specification are illustrative, and partial substitution or combination of configurations is possible between different example embodiments.

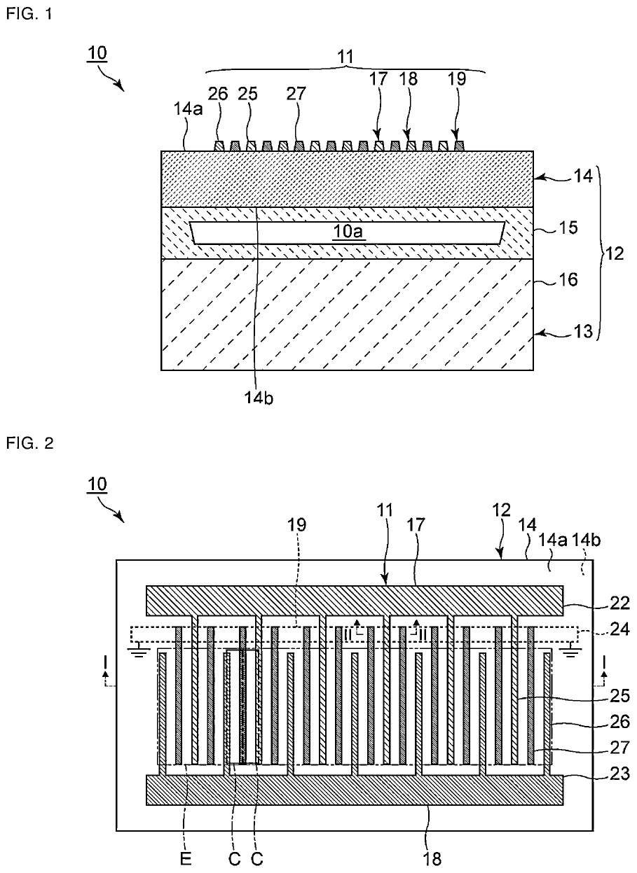

FIG. 1 is a schematic elevational cross-sectional view of an acoustic wave device according to a first example embodiment of the present invention. FIG. 2 is a schematic plan view of the acoustic wave device according to the first example embodiment. Note that FIG. 1 is a schematic cross-sectional view taken along line I-I in FIG. 2. In FIG. 2, each electrode is illustrated with hatching. In FIG. 2, a reference potential symbol is used to schematically illustrate that a reference potential electrode to be described later is connected to a reference potential. Similarly, in schematic plan views other than FIG. 2, electrodes may be hatched and the reference potential symbol may be used.

An acoustic wave device 10 illustrated in FIG. 1 is configured to be able to use a thickness-shear mode. The acoustic wave device 10 is an acoustically coupled filter. The configuration of the acoustic wave device 10 will be described below.

The acoustic wave device 10 includes a piezoelectric substrate 12 and a functional electrode 11. The piezoelectric substrate 12 includes a support 13 and a piezoelectric layer 14. In this example embodiment, the support 13 includes a support substrate 16 and an insulating layer 15. The insulating layer 15 is provided on the support substrate 16. The piezoelectric layer 14 is provided on the insulating layer 15. However, the support 13 may include the support substrate 16 only. The support 13 does not necessarily have to be provided.

The piezoelectric layer 14 includes a first main surface 14a and a second main surface 14b. The first main surface 14a and the second main surface 14b face each other. Of the first main surface 14a and the second main surface 14b, the second main surface 14b is located on the support 13 side.

As illustrated in FIG. 2, the functional electrode 11 includes a pair of comb-shaped electrodes and a reference potential electrode 19. The reference potential electrode 19 is connected to a reference potential. The pair of comb-shaped electrodes are specifically a first comb-shaped electrode 17 and a second comb-shaped electrode 18. The first comb-shaped electrode 17 is connected to an input potential. The second comb-shaped electrode 18 is connected to an output potential.

The first comb-shaped electrode 17 and the second comb-shaped electrode 18 are provided on the first main surface 14a of the piezoelectric layer 14. The first comb-shaped electrode 17 includes a first busbar 22 and a plurality of first electrode fingers 25. The plurality of first electrode fingers 25 each have one end connected to the first busbar 22. The second comb-shaped electrode 18 includes a second busbar 23 and a plurality of second electrode fingers 26. The plurality of second electrode fingers 26 each have one end connected to the second busbar 23.

The first busbar 22 and the second busbar 23 face each other. The plurality of first electrode fingers 25 and the plurality of second electrode fingers 26 are interdigitated with each other. The first electrode fingers 25 and the second electrode fingers 26 are alternately arranged in a direction orthogonal to a direction in which the first electrode fingers 25 and the second electrode fingers 26 extend.

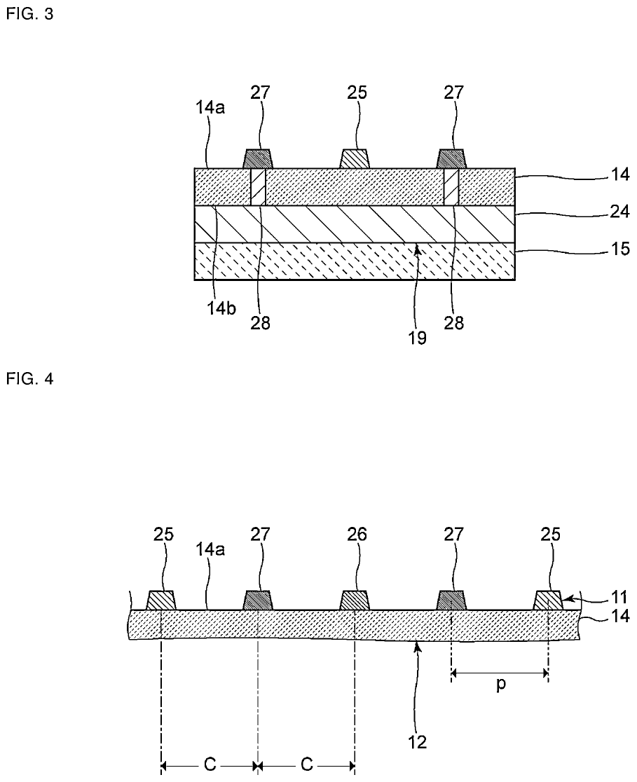

FIG. 3 is a schematic cross-sectional view taken along line II-II in FIG. 2.

The reference potential electrode 19 includes a third busbar 24, a plurality of third electrode fingers 27, and a plurality of connection electrodes 28. The plurality of third electrode fingers 27 are provided on the first main surface 14a of the piezoelectric layer 14. The plurality of third electrode fingers 27 extend parallel to the plurality of first electrode fingers 25. Hereinafter, the direction in which the first electrode fingers 25, the second electrode fingers 26, and the third electrode fingers 27 extend will be referred to as an electrode finger extending direction, and the direction orthogonal to the electrode finger extending direction will be referred to as an electrode finger orthogonal direction.

The third busbar 24 is provided on the second main surface 14b of the piezoelectric layer 14. The third busbar 24 extends in the electrode finger orthogonal direction. The third busbar 24 faces the plurality of third electrode fingers 27 across the piezoelectric layer 14. However, the direction in which the third busbar 24 extends is not limited to the above.

The plurality of connection electrodes 28 are provided so as to penetrate the piezoelectric layer 14. One connection electrode 28 connects one third electrode finger 27 to the third busbar 24. In other words, the plurality of third electrode fingers 27 are electrically connected to the third busbar 24 through the plurality of connection electrodes 28.

The third busbar 24 only needs to be provided so as to face the plurality of third electrode fingers 27 across at least the piezoelectric layer 14. Specifically, for example, the third busbar 24 may face the plurality of third electrode fingers 27 across the piezoelectric layer 14 and other layers. The plurality of connection electrodes 28 may connect the third busbar 24 to the plurality of third electrode fingers 27 by penetrating at least the piezoelectric layer 14 of the piezoelectric substrate 12.

As illustrated in FIG. 2, in this example embodiment, all of the third electrode fingers 27 are provided between the first electrode fingers 25 and the second electrode fingers 26. Therefore, the first electrode fingers 25, the second electrode fingers 26, and the third electrode fingers 27 are arranged in the direction in which the first electrode fingers 25 and the second electrode fingers 26 are arranged. When the direction in which the first electrode fingers 25, the second electrode fingers 26, and the third electrode fingers 27 are arranged is an electrode finger arrangement direction, the electrode finger arrangement direction is the electrode finger orthogonal direction. Hereinafter, the first electrode fingers 25, the second electrode fingers 26, and the third electrode fingers 27 may be collectively referred to simply as electrode fingers.

FIG. 4 is a schematic elevational cross-sectional view illustrating the vicinity of the first to third electrode fingers in the first example embodiment. Note that FIG. 4 illustrates a cross section without the connection electrodes 28 illustrated in FIG. 3. The same applies to the portion illustrated in FIG. 1 above.

As illustrated in FIG. 4, the plurality of electrode fingers are arranged in the order of, starting from the first electrode finger 25, the first electrode finger 25, the third electrode finger 27, the second electrode finger 26, and the third electrode finger 27 as one period. Therefore, the order in which the plurality of electrode fingers are arranged is the first electrode finger 25, the third electrode finger 27, the second electrode finger 26, the third electrode finger 27, the first electrode finger 25, the third electrode finger 27, the second electrode finger 26, . . . and so on. In the functional electrode 11, the electrode fingers at the end portions in the electrode finger orthogonal direction may be any of the first electrode fingers 25, the second electrode fingers 26, and the third electrode fingers 27. For example, in this example embodiment illustrated in FIG. 2, the electrode fingers located at both end portions in the electrode finger orthogonal direction are the second electrode fingers 26.

The acoustic wave device 10 includes a plurality of terminals electrically connected to the outside. In this example embodiment, these terminals are configured as electrode pads. Each of the comb-shaped electrodes and the reference potential electrode 19 are electrically connected to these terminals through appropriate wiring. The first comb-shaped electrode 17 is connected to the input potential. The second comb-shaped electrode 18 is connected to the output potential. The reference potential electrode 19 is connected to the reference potential. Each of the above terminals may be configured as wiring.

The acoustic wave device 10 is an acoustic wave resonator configured to be able to use a thickness-shear mode bulk wave. As illustrated in FIG. 2, the acoustic wave device 10 includes a plurality of excitation regions C. In the plurality of excitation regions C, the thickness-shear mode bulk waves and acoustic waves in other modes are excited. FIG. 2 illustrates only two of the plurality of excitation regions C.

Some of the plurality of excitation regions C are regions where the adjacent first electrode finger 25 and third electrode finger 27 overlap when viewed from the electrode finger orthogonal direction, and also regions between the centers of the adjacent first electrode finger 25 and third electrode finger 27. The rest of the excitation regions C are regions where the adjacent second electrode finger 26 and third electrode finger 27 overlap when viewed from the electrode finger orthogonal direction, and also regions between the centers of the adjacent second electrode finger 26 and third electrode finger 27. These excitation regions C are arranged in the electrode finger orthogonal direction. It should be noted that the excitation regions C are regions of the piezoelectric layer 14, defined based on configuration of the functional electrode 11.

This example embodiment is characterized by the following configuration. 1) The third electrode finger 27 of the reference potential electrode 19 is located between the first electrode finger 25 of the first comb-shaped electrode 17 and the second electrode finger 26 of the second comb-shaped electrode 18. 2) The plurality of connection electrodes 28 illustrated in FIG. 3 penetrate the piezoelectric layer 14, thus connecting the third busbar 24 to the plurality of third electrode fingers 27. This configuration makes it possible, when the acoustic wave device 10 is used in a filter device, to promote miniaturization of the filter device and lower the electric resistance of the wiring connected to the reference potential. This will be described below.

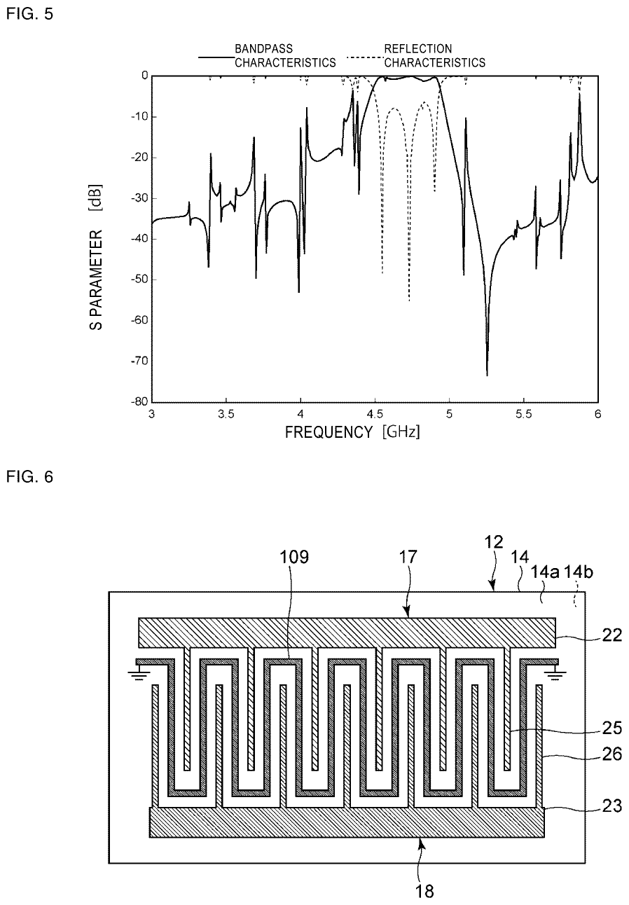

FIG. 5 illustrates an example of bandpass characteristics and reflection characteristics of the acoustic wave device 10.

FIG. 5 is a graph illustrating bandpass characteristics and reflection characteristics of the acoustic wave device according to the first example embodiment. Note that FIG. 5 illustrates the results of a finite element method (FEM) simulation.

As illustrated in FIG. 5, it can be seen that a filter waveform can be suitably obtained even with a single acoustic wave device 10. The acoustic wave device 10 is an acoustically coupled filter. More specifically, as illustrated in FIG. 2, the acoustic wave device 10 includes an excitation region C located between the centers of the adjacent first electrode finger 25 and third electrode finger 27, and an excitation region C located between the centers of the adjacent second electrode finger 26 and third electrode finger 27. In these excitation regions C, acoustic waves in a plurality of modes including a thickness-shear mode bulk wave are excited. By coupling these modes, a filter waveform can be suitably obtained even with a single acoustic wave device 10.

When the acoustic wave device 10 is used as an acoustic wave resonator in a filter device, a filter waveform can be suitably obtained even with one or a small number of acoustic wave resonators of the filter device. This makes it possible to promote the miniaturization of the filter device.

In addition, as illustrated in FIG. 3, in this example embodiment, the reference potential electrode 19 has a three-dimensional configuration. This allows the length of the reference potential electrode 19 to be shorter than in a configuration in which the reference potential electrode 19 is routed only on one main surface of the piezoelectric layer 14.

More specifically, for example, in a first reference example illustrated in FIG. 6, a reference potential electrode 109 is provided only on the first main surface 14a of the piezoelectric layer 14. A portion of the reference potential electrode 109 provided between the first comb-shaped electrode 17 and the second comb-shaped electrode 18 has a meander shape. Therefore, the overall length of the reference potential electrode 109 is long.

The reference potential electrode 109 is connected to a reference potential through a terminal electrically connected to the outside. The reference potential electrode 109 includes portions corresponding to a plurality of third electrode fingers. In the reference potential electrode 109, portions corresponding to the plurality of third electrode fingers are included between the portion corresponding to the third electrode finger located near the center and the above terminal. Therefore, the length of the reference potential electrode 109 from the portion corresponding to the third electrode finger located near the center to the portion connected to the above terminal is particularly long.

In this example embodiment illustrated in FIG. 2, on the other hand, one end of each of the third electrode fingers 27 is connected to the third busbar 24. The third busbar 24 is connected to a terminal electrically connected to the outside. Therefore, regardless of the position of the third electrode finger 27, the length of the reference potential electrode 19 from the third electrode finger 27 to the portion of the reference potential electrode 19 that is connected to the above terminal can be shortened. Therefore, the electric resistance of the reference potential electrode 19 can be lowered.

In this case, the potential stability of the reference potential electrode 19 can be improved. This makes it possible, when the acoustic wave device 10 is used in a filter device, to reduce or prevent deterioration of the filter characteristics of the filter device.

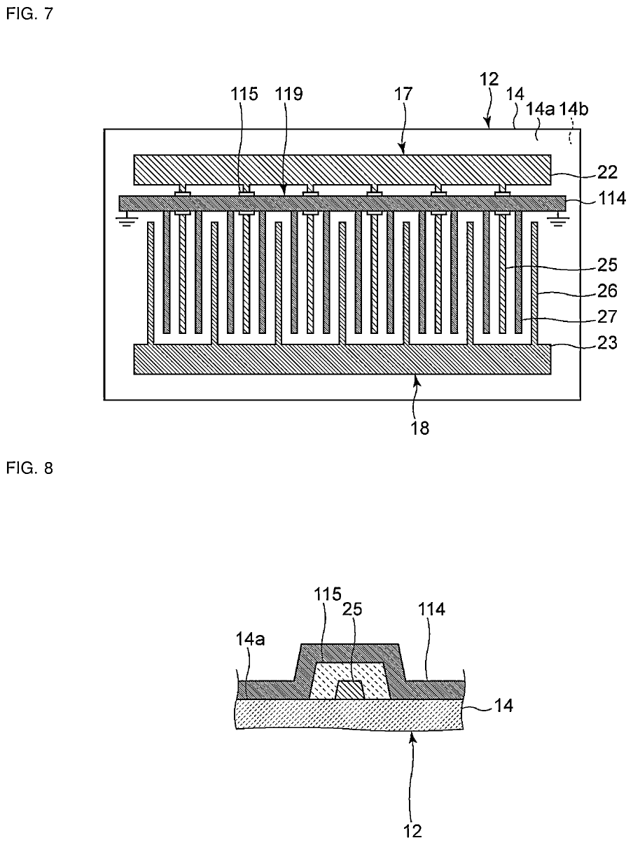

It is also conceivable, as in a second reference example illustrated in FIG. 7, that the reference potential electrode 119 has a three-dimensional configuration on the first main surface 14a of the piezoelectric layer 14. Specifically, as illustrated in FIGS. 7 and 8, in the second reference example, the first electrode finger 25 is partially covered with an insulating film 115. A third busbar 114 is provided on the first main surface 14a of the piezoelectric layer 14, on the third electrode finger 27, and on the insulating film 115. However, the first main surface 14a is provided with wiring connected to the signal potential. Therefore, the layout of the reference potential electrode 119 has a low degree of freedom. This may increase the overall length of the wiring connected to the reference potential.

In this example embodiment illustrated in FIG. 3, on the other hand, the third busbar 24 is provided on the second main surface 14b of the piezoelectric layer 14. The degree of freedom in layout is high on the second main surface 14b. Therefore, the wiring to connect the reference potential electrode 19 to the reference potential can be easily provided on the second main surface 14b without increasing the size of the acoustic wave device 10.

As illustrated in FIG. 2, it is preferable that the width of the third busbar 24 is larger than the width of the third electrode finger 27. This can effectively lower the electric resistance of the reference potential electrode 19. Note that the width of the third busbar 24 is the dimension of the third busbar 24 along a direction orthogonal to the direction in which the third busbar 24 extends. The width of the third electrode finger 27 is the dimension of the third electrode finger 27 along the electrode finger orthogonal direction.

As described above, the degree of freedom in layout is high on the second main surface 14b of the piezoelectric layer 14. Therefore, the width of the third busbar 24 can be easily increased.

The configuration of this example embodiment will be described in more detail below.

As illustrated in FIG. 1, the support 13 includes the support substrate 16 and the insulating layer 15. The piezoelectric substrate 12 is a multilayer body of the support substrate 16, the insulating layer 15, and the piezoelectric layer 14. Specifically, the piezoelectric layer 14 and the support 13 overlap when viewed from the direction in which the first main surface 14a and the second main surface 14b of the piezoelectric layer 14 face each other.

Examples of the material of the support substrate 16 include a semiconductor such as silicon, ceramics such as aluminum oxide, and the like. The insulating layer 15 can be made of an appropriate dielectric such as silicon oxide or tantalum oxide. The piezoelectric layer 14 may be, for example, a lithium niobate layer such as a LiNbO₃ layer or a lithium tantalate layer such as a LiTaO₃ layer.

The insulating layer 15 has a hollow portion. Specifically, a hollow portion is formed as a cavity 10a in the insulating layer 15. In this example embodiment, the insulating layer 15 covers the second main surface 14b of the piezoelectric layer 14. As illustrated in FIG. 3, the insulating layer 15 covers the third busbar 24 of the reference potential electrode 19.

However, the configuration of the cavity 10a illustrated in FIG. 1 is not limited to the above. For example, a recess portion may be provided in the insulating layer 15. The piezoelectric layer 14 may be provided on the insulating layer 15 so as to close this recess portion. Thus, a cavity 10a may be formed. In this case, the support 13 and the piezoelectric layer 14 are disposed so that a portion of the support 13 and a portion of the piezoelectric layer 14 face each other across the cavity 10a. The recess portion in the support 13 may be provided across the insulating layer 15 and the support substrate 16. Alternatively, a recess portion provided only in the support substrate 16 may be closed by the insulating layer 15. The recess portion may be provided in the piezoelectric layer 14. The cavity 10a may be a through-hole provided in the support 13.

The cavity 10a is an acoustic reflection portion in an example embodiment of the present invention. The acoustic reflection portion can effectively confine the energy of the acoustic wave to the piezoelectric layer 14 side. The acoustic reflection portion may be provided at a position on the support 13 that overlaps at least a part of the functional electrode 11 in plan view. More specifically, the first electrode finger 25, the second electrode finger 26, and the third electrode finger 27 may each at least partially overlap with the acoustic reflection portion in plan view. In plan view, a plurality of excitation regions C preferably overlap with the acoustic reflection portion.

In this specification, a plan view refers to a view along the lamination direction of the support 13 and the piezoelectric layer 14 from a direction corresponding to the upper side in FIG. 1. In FIG. 1, for example, of the support substrate 16 side and the piezoelectric layer 14 side, the piezoelectric layer 14 side is the upper side. Furthermore, in this specification, the plan view is synonymous with a view from a main surface facing direction. The main surface facing direction is a direction in which the first main surface 14a and the second main surface 14b of the piezoelectric layer 14 face each other. More specifically, the main surface facing direction is, for example, a normal direction of the first main surface 14a.

The acoustic reflection portion may be an acoustic reflection film such as an acoustic multilayer film, which will be described later. For example, the acoustic reflection film may be provided on the surface of the support.

In the first example embodiment, the center-to-center distance between a plurality of pairs of first electrode fingers 25 and third electrode fingers 27 adjacent to each other is the same as the center-to-center distance between a plurality of pairs of second electrode fingers 26 and third electrode fingers 27 adjacent to each other. In this case, d/p is preferably less than or equal to, for example, about 0.5, more preferably less than or equal to about 0.24, where d is the thickness of the piezoelectric layer 14 and p is the center-to-center distance between adjacent electrode fingers. This allows for better excitation of the thickness-shear mode bulk wave.

However, the center-to-center distance between the adjacent first electrode finger 25 and third electrode finger 27 and the center-to-center distance between the adjacent second electrode finger 26 and third electrode finger 27 do not have to be constant. In this case, it is preferable that p is the longest distance of the center-to-center distance between the adjacent first electrode finger 25 and third electrode finger 27 and the center-to-center distance between the adjacent second electrode finger 26 and third electrode finger 27. In this case, d/p is preferably less than or equal to about 0.5, more preferably less than or equal to about 0.24, for example. Note that an acoustic wave device according to an example embodiment of the present invention does not necessarily have to be configured to be able to use the thickness-shear mode.

As illustrated in FIG. 2, when viewed from the electrode finger orthogonal direction, the region where the adjacent first electrode finger 25 and third electrode finger 27 or the adjacent second electrode finger 26 and third electrode finger 27 overlap each other is an intersection region E. The intersection region E includes a plurality of excitation regions C. An acoustic wave device according to an example embodiment of the present invention may be configured to be able to use a plate wave. In this case, the excitation region is the intersection region E.

In plan view, the third busbar 24 overlaps with a portion including one end of each of the third electrode fingers 27. This allows the third electrode finger 27 to be disposed between the first electrode finger 25 and the second electrode finger 26 without making the third electrode finger 27 too long. The length of the third electrode finger 27 is the dimension of the third electrode finger 27 along the electrode finger extending direction.

In plan view, the third busbar 24 is provided in a portion of the intersection region E that overlaps with the outer side portion in the electrode finger extending direction. Specifically, in plan view, the third busbar 24 overlaps with a region between the first busbar 22 and the plurality of second electrode fingers 26. Note that the third busbar 24 may overlap with a region between the second busbar 23 and the plurality of first electrode fingers 25 in plan view.

In this example embodiment, the piezoelectric layer 14 is the lithium niobate layer. Specifically, a LiNbO₃ of a rotated X-cut is used as the piezoelectric layer 14. In this case, the fractional band width of the acoustic wave device 10 depends on the Euler angles (φ, θ, ψ) of the lithium niobate used in the piezoelectric layer 14. The fractional band width is expressed by (|fa−fr|/fr)×100[%], where fr is the resonant frequency and fa is the anti-resonant frequency.

The relationship between the fractional band width of the acoustic wave device 10 and the Euler angles (φ, θ, ψ) of the piezoelectric layer 14 when d/p is infinitely close to 0 is derived. Note that φ in the Euler angles is set to 0°.

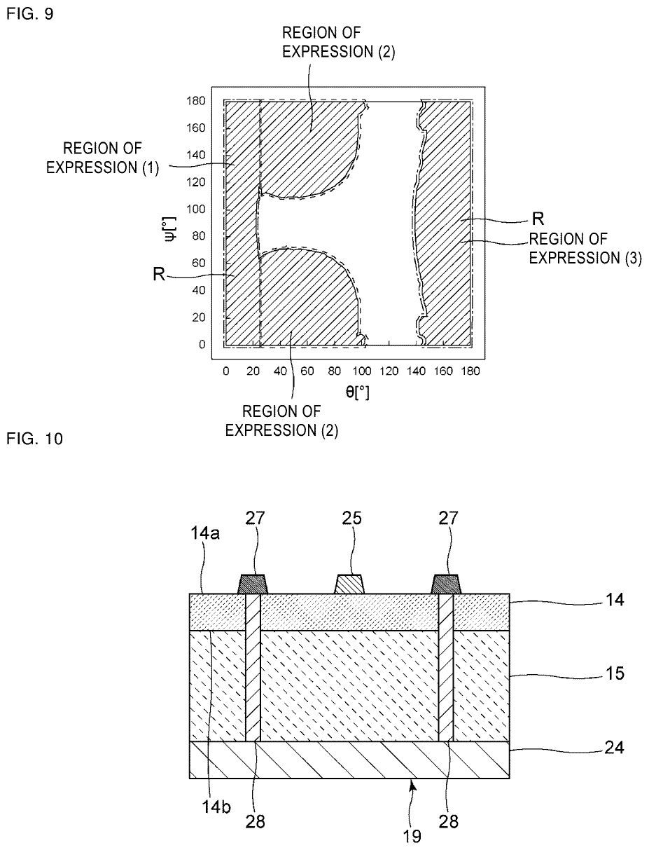

FIG. 9 is a diagram illustrating a map of a fractional band width with respect to the Euler angles (0°, θ, ψ) of LiNbO₃ when d/p is infinitely close to 0.

A hatched region R in FIG. 9 is a region where the fractional band width of at least more than or equal to about 2% is obtained, for example. When φ in the Euler angles (φ, θ, ψ) is within the range of about 0°±10°, for example, the relationship between θ and ψ and the fractional band width is the same as that illustrated in FIG. 9. Also in the case where the piezoelectric layer 14 is a lithium tantalate layer, when φ is within the range of about 0°±10°, for example, the relationship between θ and ψ and the fractional band width is the same as that illustrated in FIG. 9. The range of the region R is approximated by the following Expressions (1), (2), and (3).

(within the range of 0°±10°,0° to 25°, any ψ) Expression (1)

(within the range of 0°±10°,25° to 100°,75°[(1−(θ−50)²/2500)]^{1/2} or 180°−75°[(1−(θ−50)²/2500)]^{1/2} to 180°) Expression (2)

(within the range of 0°±10°,180°−40°[(1−(ψ−90)²/8100)]^{1/2} to 180°, any ψ) Expression (3)

It is preferable that the Euler angles are within the range of Expression (1), Expression (2), or Expression (3). This allows the fractional band width to be sufficiently widened, thus making it possible to suitably use the acoustic wave device 10 in a filter device.

The position where the third busbar 24 of the reference potential electrode 19 illustrated in FIG. 3 is provided is not limited to the second main surface 14b of the piezoelectric layer 14. For example, in a modification of the first example embodiment illustrated in FIG. 10, the third busbar 24 is provided on the insulating layer 15. The third busbar 24 is located in a cavity. The third busbar 24 faces the piezoelectric layer 14 across the insulating layer 15. The third busbar 24 faces the plurality of third electrode fingers 27 across the insulating layer 15 and the piezoelectric layer 14. Each connection electrode 28 penetrates the piezoelectric layer 14 and the insulating layer 15. Each third electrode finger 27 is electrically connected to the third busbar 24 through each connection electrode 28.

The third busbar 24 may be embedded in the insulating layer 15. Specifically, the third busbar 24 may be provided between the second main surface 14b of the piezoelectric layer 14 and the surface of the insulating layer 15 on the cavity side. In this case, the third busbar 24 and the plurality of third electrode fingers 27 may be electrically connected by the plurality of connection electrodes 28.

In this modification and in the case where the third busbar 24 is provided in the insulating layer 15, the miniaturization of the filter device can be promoted, as in the first example embodiment, and the electric resistance of the wiring connected to the reference potential can be lowered.

In the first example embodiment and this modification, the width of the connection electrode 28 is narrower than that of the third electrode finger 27. However, the width of the connection electrode 28 may be larger than or equal to the width of the third electrode finger 27. The width of the connection electrode 28 refers to the dimension of the connection electrode 28 in the electrode finger orthogonal direction.

A dielectric film may be provided on the first main surface 14a of the piezoelectric layer 14 so as to cover the plurality of electrode fingers. In this case, the plurality of electrode fingers are protected by the dielectric film, and therefore the electrode fingers are less likely to be damaged. An acoustic device according to an example embodiment of the present invention may have, for example, a wafer level package (WLP) structure. Alternatively, an acoustic wave device according to an example embodiment of the present invention may have a configuration in which an acoustic wave resonator is mounted on a mounting substrate. In these cases, the third busbar of the reference potential electrode may be provided in a portion other than the piezoelectric substrate. These examples will be described in second and third example embodiments.

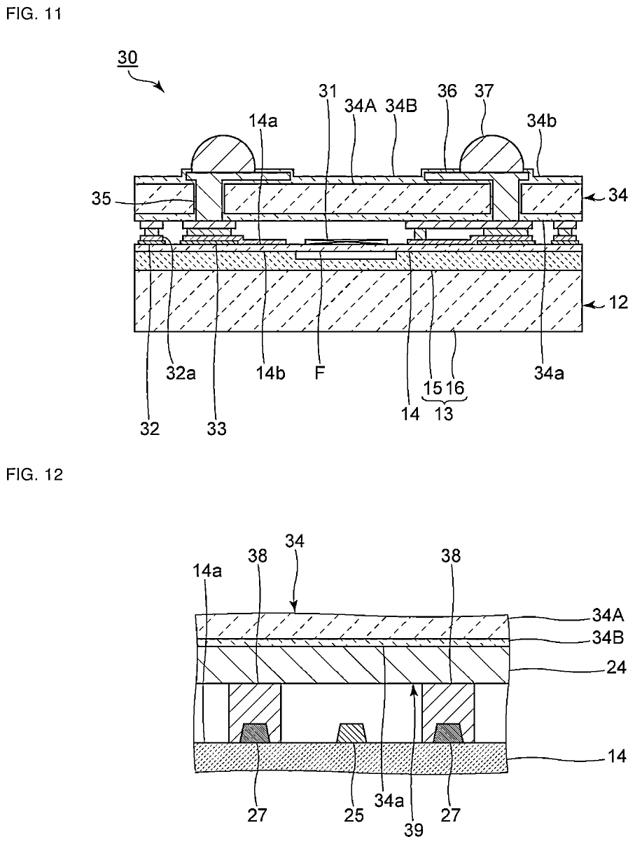

FIG. 11 is a schematic elevational cross-sectional view of an acoustic wave device according to a second example embodiment. In FIG. 11, a portion in which each comb-shaped electrode and a plurality of third electrode fingers are provided is illustrated in a schematic diagram in which two diagonal lines are added to a rectangle. The same applies to schematic elevational cross-sectional views other than FIG. 11. Note that FIG. 11 illustrates a cross section of a portion of a reference potential electrode where a third busbar and a connection electrode are not provided.

An acoustic wave device 30 according to this example embodiment has a WLP structure. Specifically, a first support 32 is provided on a piezoelectric substrate 12 as a support. More specifically, the first support 32 is provided on a first main surface 14a of a piezoelectric layer 14. The first support 32 has a frame shape. Therefore, the first support 32 has a cavity 32a.

A first comb-shaped electrode, a second comb-shaped electrode, and a plurality of third electrode fingers of a functional electrode 31 are provided on the first main surface 14a of the piezoelectric layer 14. When a portion of the piezoelectric layer 14 where the comb-shaped electrodes and the plurality of third electrode fingers are provided is defined as an element electrode forming portion F, the element electrode forming portion F is located inside the cavity 32a.

A plurality of second supports 33 are provided on the first main surface 14a of the piezoelectric layer 14. The second support 33 has a columnar shape. The plurality of second supports 33 are located inside the cavity 32a of the first support 32. In this example embodiment, the first support 32 and the second supports 33 are each a multilayer body of a plurality of metal layers. Note that the second supports 33 do not necessarily have to be provided.

A cover 34 is provided on the first support 32 and the plurality of second supports 33 so as to cover the cavity 32a. A hollow portion is thus provided, which is surrounded by the piezoelectric substrate 12, the first support 32, and the cover 34. The element electrode forming portion F is located inside this hollow portion.

The cover 34 includes a cover main body 34A and an inorganic oxide layer 34B. The cover main body 34A includes a pair of main surfaces. Both main surfaces face each other. One main surface of the cover main body 34A faces the piezoelectric substrate 12. The inorganic oxide layer 34B is provided on both main surfaces of the cover main body 34A. The main surface of the cover 34 is the surface of the inorganic oxide layer 34B in the portion that is provided on the main surface of the cover main body 34A.

More specifically, the cover 34 includes a third main surface 34a and a fourth main surface 34b. The third main surface 34a and the fourth main surface 34b face each other. Of the third main surface 34a and the fourth main surface 34b, the third main surface 34a is the main surface on the piezoelectric substrate 12 side. However, the inorganic oxide layer 34B does not have to be provided. In this case, the third main surface 34a and the fourth main surface 34b of the cover 34 are the main surfaces of the cover main body 34A.

In this example embodiment, the cover main body 34A is a silicon substrate. The support substrate 16 of the piezoelectric substrate 12 is also a silicon substrate. However, the materials of the support substrate 16 and the cover main body 34A are not limited to the above.

The cover 34 is provided with a through electrode 35. More specifically, a through-hole is provided in the cover 34. The through-hole is provided so as to reach the second support 33. The through electrode 35 is provided in the through-hole. One end of the through electrode 35 is connected to the second support 33. An external terminal 36 is provided so as to be connected to the other end of the through electrode 35. The external terminal 36 is configured as an electrode pad. In this example embodiment, the through electrode 35 and the external terminal 36 are integrally formed. However, the through electrode 35 and the external terminal 36 may be provided separately.

The inorganic oxide layer 34B of the cover 34 is provided not only on the main surface of the cover main body 34A, but also inside the through-hole. More specifically, inside the through-hole, the inorganic oxide layer 34B is located between the through electrode 35 and the cover main body 34A. The inorganic oxide layer 34B is provided so as to cover the vicinity of the outer periphery of the external terminal 36. The inorganic oxide layer 34B reaches between the external terminal 36 and the cover main body 34A. The inorganic oxide layer 34B is, for example, a silicon oxide layer. However, the material of the inorganic oxide layer 34B is not limited to the above.

The inorganic oxide layer 34B does not have to be provided inside the through-hole of the cover main body 34A. The inorganic oxide layer 34B does not have to be provided on the external terminal 36 or between the external terminal 36 and the cover main body 34A.

Bumps 37 are provided as conductive bonds on the portions of the plurality of external terminals 36 that are not covered with the inorganic oxide layer 34B. The bumps 37 may be, for example, solder bumps or Au bumps. The conductive bonding member may be, for example, a conductive adhesive. The conductive bonding member is electrically connected to an external reference potential or signal potential.

FIG. 12 is a schematic elevational cross-sectional view illustrating an enlarged portion of the acoustic wave device according to the second example embodiment.

The third busbar 24 of the reference potential electrode 39 in this example embodiment is provided on the third main surface 34a of the cover 34. The third busbar 24 faces the plurality of third electrode fingers 27.

The plurality of connection electrodes 38 of the reference potential electrode 39 are provided between the first main surface 14a of the piezoelectric layer 14 and the cover 34. The connection electrodes 38 are columnar electrodes. More specifically, each connection electrode 38 is provided on one third electrode finger 27 and on the piezoelectric layer 14. Each connection electrode 38 is connected to the third busbar 24. That is, the plurality of connection electrodes 38 connect the third busbar 24 to the plurality of third electrode fingers 27. This lowers the electric resistance of the reference potential electrode 39.

Each connection electrode 38 only needs to be provided on at least the third electrode finger 27. At least one connection electrode 38 may be provided only on the third electrode finger 27. In this case, the connection electrode 38 is not provided directly on the piezoelectric layer 14.

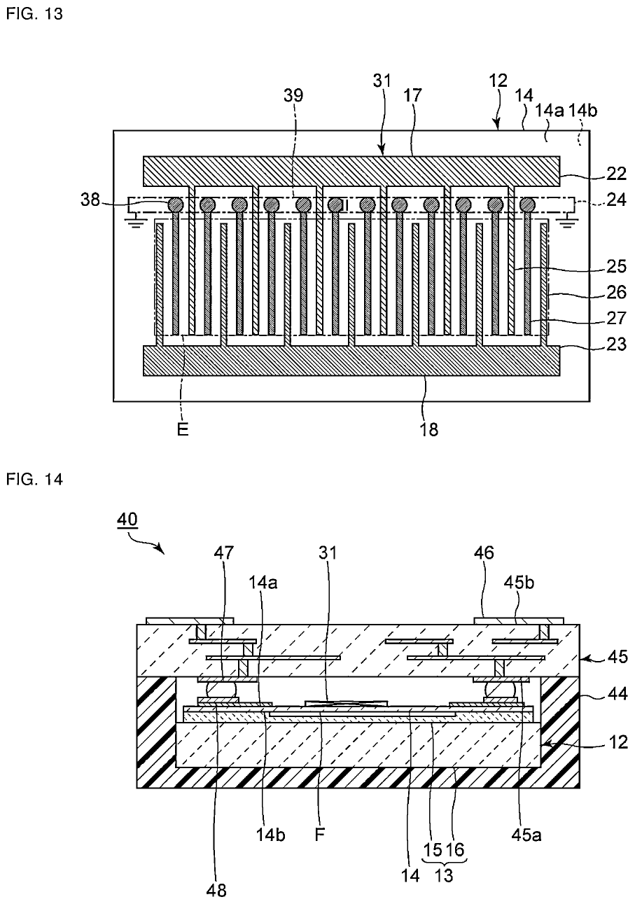

FIG. 13 is a schematic plan view illustrating an electrode configuration on the first main surface of the piezoelectric layer in the second example embodiment.

In plan view, the third busbar 24 is provided in a portion of the intersection region E that overlaps with the outer side portion in the electrode finger extending direction. Specifically, in plan view, the third busbar 24 overlaps with a region between the first busbar 22 and the plurality of second electrode fingers 26. Note that the third busbar 24 may overlap with a region between the second busbar 23 and the plurality of first electrode fingers 25 in plan view.

The third busbar 24 is electrically connected to the reference potential through other wiring, the through electrodes 35 and the bumps 37 illustrated in FIG. 11. The layout on the third main surface 34a of the cover 34 has a high degree of freedom. Therefore, wiring to connect the reference potential electrode 39 to a reference potential can be easily provided on the third main surface 34a, without increasing the size of the acoustic wave device 30. The width of the third busbar 24 can also be easily increased. This makes it possible to easily and effectively lower the electric resistance of the reference potential electrode 39.

Furthermore, the acoustic wave device 30 of this example embodiment is an acoustically coupled filter, as in the first example embodiment. Therefore, when the acoustic wave device 30 is used as an acoustic wave resonator in a filter device, a filter waveform can be suitably obtained even when the filter device includes only one or a small number of acoustic wave resonators. This makes it possible to promote the miniaturization of the filter device and lower the electric resistance of the wiring connected to the reference potential.

The first support 32 may be provided on a layer other than the piezoelectric layer 14 of the piezoelectric substrate 12. More specifically, the support 13 is a multilayer body of the support substrate 16 and the insulating layer 15, as in the first example embodiment. For example, the outer periphery of the piezoelectric layer 14 may be located inside the outer periphery of the insulating layer 15 or the support substrate 16 in plan view. In this case, the first support 32 may be provided on the insulating layer 15 or the support substrate 16.

FIG. 14 is a schematic elevational cross-sectional view of an acoustic wave device according to a third example embodiment.

An acoustic wave device 40 has a configuration in which an acoustic wave resonator is mounted on a mounting substrate 45. Specifically, the acoustic wave device 40 has a chip size package (CSP) structure. The mounting substrate 45 is a printed circuit board (PCB). In this example embodiment, the material of the mounting substrate 45 is high-temperature co-fired ceramic (HTCC). However, the material of the mounting substrate 45 is not limited to the above.

On the other hand, the support substrate 16 in the piezoelectric substrate 12 is a silicon substrate. However, the material of the support substrate 16 is not limited to the above.

A plurality of conductive bonds are provided on the piezoelectric substrate 12. More specifically, a plurality of electrode pads 48 are provided on the piezoelectric substrate 12. The conductive bonds are provided on the plurality of electrode pads 48, respectively. In this example embodiment, the conductive bonds are bumps 47, for example. The bumps 47 may be, for example, solder bumps or Au bumps.

The piezoelectric substrate 12 is bonded to the mounting substrate 45 by the plurality of conductive bonds. The mounting substrate 45 includes a fifth main surface 45a and a sixth main surface 45b. Of the fifth main surface 45a and the sixth main surface 45b, the fifth main surface 45a is the main surface on the piezoelectric substrate 12 side. The fifth main surface 45a is provided with a sealing resin 44 so as to cover the support substrate 16 of the piezoelectric substrate 12. The piezoelectric substrate 12, the sealing resin 44, and the mounting substrate 45 form a hollow portion. An element electrode forming portion F of the piezoelectric layer 14 is located inside this hollow portion.

A plurality of external terminals 46 are provided on the sixth main surface 45b of the mounting substrate 45. A plurality of via electrodes and a plurality of wirings are provided in the mounting substrate 45. Each external terminal 46 is electrically connected to the via electrode and wiring in the mounting substrate 45. Each of the plurality of external terminals 46 is electrically connected to an external reference potential or signal potential through a bump, a conductive adhesive, or the like.

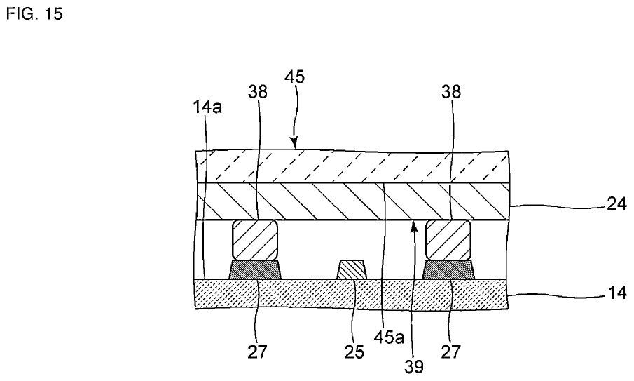

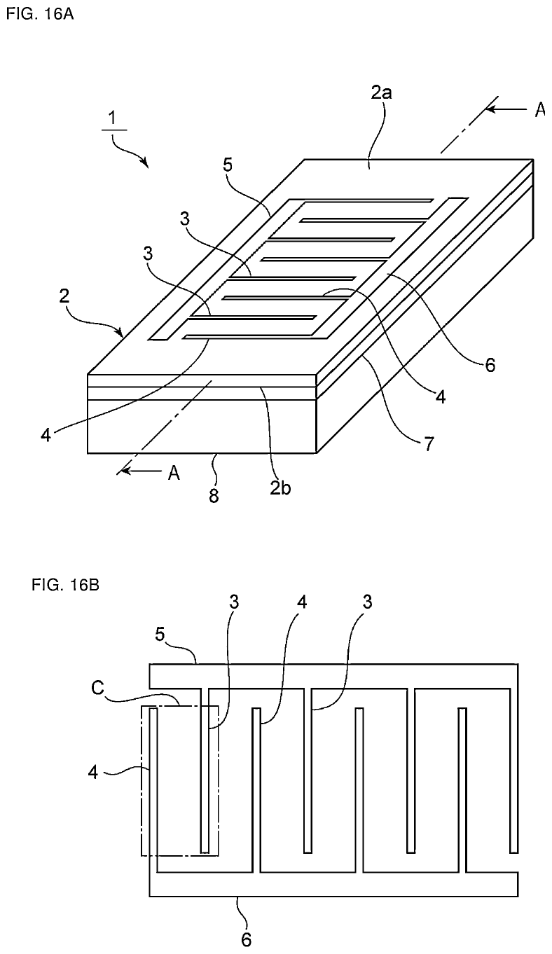

FIG. 15 is a schematic elevational cross-sectional view illustrating an enlarged portion of the acoustic wave device according to the third example embodiment.

A third busbar 24 of a reference potential electrode 39 in this example embodiment is provided on the fifth main surface 45a of the mounting substrate 45. The third busbar 24 faces the plurality of third electrode fingers 27.

A plurality of connection electrodes 38 of the reference potential electrode 39 are provided between the first main surface 14a of the piezoelectric layer 14 and the fifth main surface 45a of the mounting substrate 45. The connection electrodes 38 are columnar electrodes. More specifically, each connection electrode 38 is provided only on one third electrode finger 27. Each connection electrode 38 is connected to the third busbar 24. That is, the plurality of connection electrodes 38 connect the third busbar 24 to the plurality of third electrode fingers 27, thus lowering the electric resistance of the reference potential electrode 39.

Note that each connection electrode 38 only needs to be provided on at least the third electrode finger 27. At least one connection electrode 38 may be provided on the third electrode finger 27 on the piezoelectric layer 14.

As in the third example embodiment illustrated in FIG. 13, the third busbar 24 is provided in a portion of the intersection region E that overlaps with the outer side portion in the electrode finger extending direction in plan view. Specifically, the third busbar 24 overlaps with the region between the first busbar 22 and the plurality of second electrode fingers 26 in plan view. The third busbar 24 may also overlap with the region between the second busbar 23 and the plurality of first electrode fingers 25 in plan view.

The third busbar 24 is electrically connected to the reference potential through the wiring on the fifth main surface 45a of the mounting substrate 45 illustrated in FIG. 14, the wiring and via electrodes in the mounting substrate 45, and the external terminal 46. The layout on the fifth main surface 45a has a high degree of freedom. Therefore, wiring to connect the reference potential electrode 39 to the reference potential can be easily provided on the fifth main surface 45a without increasing the size of the acoustic wave device 40. The width of the third busbar 24 can also be easily increased. This makes it possible to easily and effectively lower the electric resistance of the reference potential electrode 39.

Furthermore, the acoustic wave device 40 of this example embodiment is an acoustically coupled filter, as in the first example embodiment. Therefore, when the acoustic wave device 40 is used as an acoustic wave resonator in a filter device, a filter waveform can be suitably obtained even when the filter device includes only one or a small number of acoustic wave resonators. This makes it possible to promote the miniaturization of the filter device and to lower the electric resistance of the wiring connected to the reference potential.

The thickness-shear mode will be described in detail below using an example where the functional electrode is an IDT electrode. Note that the IDT electrode has no third electrode fingers. The “electrode” in the IDT electrode described below corresponds to the electrode finger. A support in the following example corresponds to the support substrate. The reference potential may be hereinafter referred to as a ground potential.

FIG. 16A is a schematic perspective view illustrating an appearance of an acoustic wave device that uses a thickness-shear mode bulk wave. FIG. 16B is a plan view illustrating an electrode structure on a piezoelectric layer. FIG. 17 is a cross-sectional view of a portion taken along line A-A in FIG. 16A.

An acoustic wave device 1 includes a piezoelectric layer 2 made of LiNbO₃. The piezoelectric layer 2 may be made of LiTaO₃. The cut-angle of LiNbO₃ or LiTaO₃ is a Z-cut in this example embodiment, but may be a rotated Y-cut or X-cut. The thickness of the piezoelectric layer 2 is not particularly limited, but is preferably more than or equal to about 40 nm and less than or equal to about 1000 nm, more preferably more than or equal to about 50 nm and less than or equal to about 1000 nm, for example, in order to effectively excite a thickness-shear mode. The piezoelectric layer 2 includes a first main surface 2a and a second main surface 2b facing each other. An electrode 3 and an electrode 4 are provided on the first main surface 2a. Here, the electrode 3 is an example of a “first electrode” and the electrode 4 is an example of a “second electrode”. In FIGS. 16A and 16B, a plurality of the electrodes 3 are connected to a first busbar 5. A plurality of the electrodes 4 are connected to a second busbar 6. The plurality of electrodes 3 and the plurality of electrodes 4 are interdigitated with each other. The electrode 3 and the electrode 4 have a rectangular shape and have a length direction. In a direction orthogonal to the length direction, the electrode 3 and the electrode 4 adjacent thereto face each other. The length direction of the electrodes 3 and 4 and the direction orthogonal to the length direction of the electrodes 3 and 4 each are a direction intersecting a thickness direction of the piezoelectric layer 2. Therefore, it can also be said that the electrode 3 and the electrode 4 adjacent thereto face each other in the direction intersecting the thickness direction of the piezoelectric layer 2. The length direction of the electrodes 3 and 4 may be replaced with the direction orthogonal to the length direction of the electrodes 3 and 4 illustrated in FIGS. 16A and 16B. That is, the electrodes 3 and 4 may extend in the direction in which the first busbar 5 and the second busbar 6 extend in FIGS. 16A and 16B. In this case, the first busbar 5 and the second busbar 6 extend in the direction in which the electrodes 3 and 4 extend in FIGS. 16A and 16B. A plurality of pairs of structures in which the electrode 3 connected to one potential and the electrode 4 connected to the other potential are adjacent to each other are provided in the direction orthogonal to the length direction of the electrodes 3 and 4 described above. Here, the electrode 3 and the electrode 4 being adjacent to each other refers not to a case where the electrode 3 and the electrode 4 are arranged so as to be in direct contact with each other but to a case where the electrode 3 and the electrode 4 are arranged with an interval therebetween. When the electrode 3 and the electrode 4 are adjacent to each other, an electrode connected to a hot electrode or a ground electrode, including the other electrodes 3 and 4, is not arranged between the electrode 3 and the electrode 4. The number of pairs need not be integer pairs, but may be 1.5 pairs, 2.5 pairs, or the like, for example. The center-to-center distance between the electrodes 3 and 4, that is, the pitch is preferably in the range of more than or equal to about 1 μm and less than or equal to about 10 μm, for example. In addition, the width of the electrodes 3 and 4, that is, the dimension of the electrodes 3 and 4 in their facing direction, is preferably in the range of more than or equal to about 50 nm and less than or equal to about 1000 nm, more preferably in the range of more than or equal to about 150 nm and less than or equal to about 1000 nm, for example. Note that the center-to-center distance between the electrodes 3 and 4 is a distance connecting the center of the dimension (width dimension) of the electrode 3 in the direction orthogonal to the length direction of the electrode 3 and the center of the dimension (width dimension) of the electrode 4 in the direction orthogonal to the length direction of the electrode 4.

In the acoustic wave device 1, since the Z-cut piezoelectric layer is used, the direction orthogonal to the length direction of the electrodes 3 and 4 is a direction orthogonal to the polarization direction of the piezoelectric layer 2. This does not apply when a piezoelectric body of another cut-angle is used as the piezoelectric layer 2. Here, the term “orthogonal” is not limited to strictly orthogonal but may be substantially orthogonal (an angle between the direction orthogonal to the length direction of the electrodes 3 and 4 and the polarization direction is, for example, about 90°±) 10°.

A support 8 is laminated on the second main surface 2b side of the piezoelectric layer 2 with an insulating layer 7 interposed therebetween. The insulating layer 7 and the support 8 have a frame shape and include through-holes 7a and 8a as illustrated in FIG. 17. A cavity 9 is thus provided. The cavity 9 is provided so as not to interfere with the vibration of an excitation region C of the piezoelectric layer 2. Therefore, the support 8 is laminated on the second main surface 2b with the insulating layer 7 interposed therebetween at a position not overlapping with a portion where at least a pair of electrodes 3 and 4 are provided. Note that the insulating layer 7 need not be provided. Therefore, the support 8 can be directly or indirectly laminated on the second main surface 2b of the piezoelectric layer 2.

The insulating layer 7 is made of silicon oxide. However, the insulating layer 7 can be made of an appropriate insulating material such as silicon oxynitride or alumina in addition to silicon oxide. The support 8 is made of Si. The plane orientation of the surface of Si on the piezoelectric layer 2 side may be (100), (110), or (111). Preferably, high-resistance Si including the support 8 of more than or equal to about 4 kQ cm is preferable, for example. However, the support 8 can also be made using an appropriate insulating material or semiconductor material.

Examples of the material of the support 8 include piezoelectric bodies such as aluminum oxide, lithium tantalate, lithium niobate, or quartz crystal, various ceramics such as alumina, magnesia, sapphire, silicon nitride, aluminum nitride, silicon carbide, zirconia, cordierite, mullite, steatite, or forsterite, dielectrics such as diamond or glass, semiconductors such as gallium nitride, or the like.

The plurality of electrodes 3 and 4 and the first and second busbars 5 and 6 are made of an appropriate metal or alloy such as Al or an AlCu alloy. In the acoustic wave device 1, the electrodes 3 and 4 and the first and second busbars 5 and 6 have a structure in which an Al film is laminated on a Ti film. A close contact layer other than the Ti film may be used.

At the time of driving, an AC voltage is applied between the plurality of electrodes 3 and the plurality of electrodes 4. More specifically, an AC voltage is applied between the first busbar 5 and the second busbar 6. This makes it possible to obtain resonance characteristics using a bulk wave in the thickness-shear mode excited in the piezoelectric layer 2. In the acoustic wave device 1, d/p is less than or equal to about 0.5, for example, where d is the thickness of the piezoelectric layer 2, and p is the center-to-center distance between any adjacent electrodes 3 and 4 of the plurality of pairs of electrodes 3 and 4. Therefore, the bulk wave in the thickness-shear mode is effectively excited, and good resonance characteristics can be obtained. More preferably, d/p is less than or equal to about 0.24, for example, in which case even better resonance characteristics can be obtained.

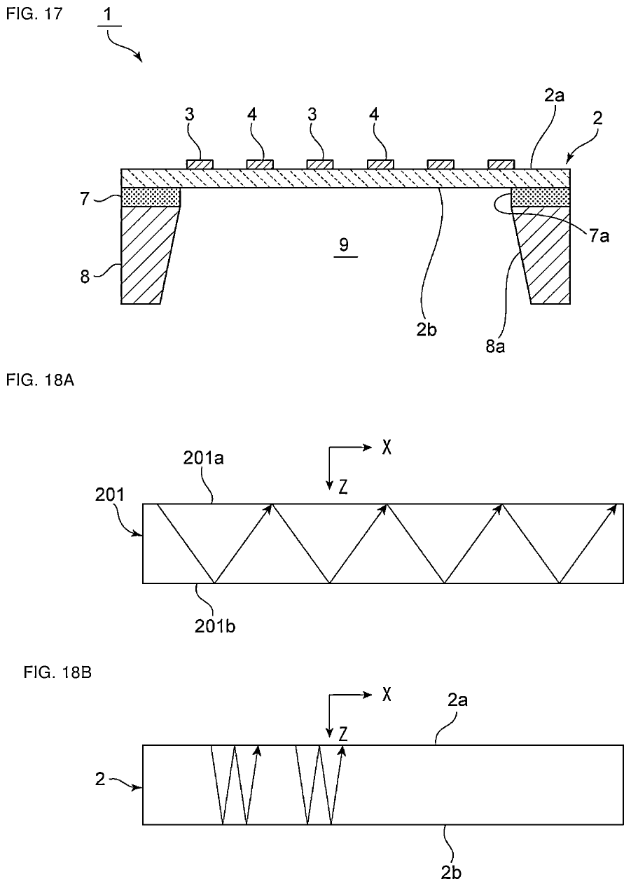

Since the acoustic wave device 1 has the configuration described above, even when the number of pairs of the electrodes 3 and 4 is reduced in an attempt for miniaturization, Q value is not easily reduced. This is because the propagation loss is small even if the number of electrode fingers in the reflectors on both sides is reduced. In addition, the reason why the number of electrode fingers can be reduced is that the bulk wave in the thickness-shear mode is used. The difference between a Lamb wave used in an acoustic wave device and the thickness-shear mode bulk wave described above will be described with reference to FIGS. 18A and 18B.

FIG. 18A is a schematic elevational cross-sectional view for explaining a Lamb wave propagating through a piezoelectric film of an acoustic wave device as described in Japanese Unexamined Patent Application Publication No. 2012-257019. As illustrated in FIG. 18A, a wave propagates through a piezoelectric film 201 as indicated by arrows. Here, the piezoelectric film 201 includes a first main surface 201a and a second main surface 201b, which face each other, and a thickness direction connecting the first main surface 201a and the second main surface 201b is the Z direction. The X direction is a direction in which electrode fingers of an IDT electrode are arranged. As illustrated in FIG. 18A, the Lamb wave propagates in the X direction. Although the piezoelectric film 201 vibrates as a whole because of the plate wave, since the wave propagates in the X direction, reflectors are arranged on both sides to obtain resonance characteristics. Therefore, a propagation loss of waves occurs, and the Q value decreases when the size is reduced, that is, when the number of pairs of electrode fingers is reduced.

On the other hand, as illustrated in FIG. 18B, in the acoustic wave device 1, since the vibration displacement is in the thickness-shear direction, the wave substantially propagates in the direction connecting the first main surface 2a and the second main surface 2b of the piezoelectric layer 2, that is, the Z direction, and resonates. Specifically, the X direction component of the wave is significantly smaller than the Z direction component. Since resonance characteristics are obtained by the propagation of the wave in the Z direction, propagation loss does not easily occur even when the number of electrode fingers of the reflector is reduced. Furthermore, even when the number of pairs of electrodes consisting of the electrodes 3 and 4 is reduced in an attempt to promote miniaturization, the Q value is not easily reduced.

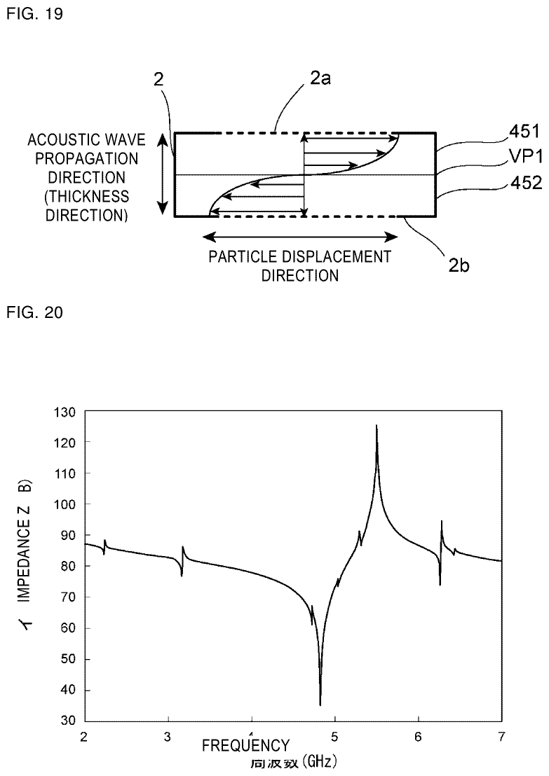

As illustrated in FIG. 19, the amplitude direction of the bulk wave in the thickness-shear mode in a first region 451 included in the excitation region C of the piezoelectric layer 2 is the opposite in a second region 452 included in the excitation region C. FIG. 19 schematically illustrates a bulk wave when a voltage is applied between the electrode 3 and the electrode 4 so that the electrode 4 has a higher potential than the electrode 3. The first region 451 is a region between the first main surface 2a and a virtual plane VP1 that is orthogonal to the thickness direction of the piezoelectric layer 2 and divides the piezoelectric layer 2 into two parts in the excitation region C. The second region 452 is a region between the virtual plane VP1 and the second main surface 2b in the excitation region C.

As described above, in the acoustic wave device 1, at least a pair of electrodes including the electrode 3 and the electrode 4 are arranged. However, since waves are not propagated in the X direction, the plurality of pairs of electrodes including the electrodes 3 and 4 are not always necessary. That is, only at least a pair of electrodes may be provided.

For example, the electrode 3 is an electrode connected to the hot potential, and the electrode 4 is an electrode connected to the ground potential. However, the electrode 3 may be connected to the ground potential and the electrode 4 may be connected to the hot potential. In the acoustic wave device 1, as described above, at least a pair of electrodes are the electrode connected to the hot potential or the electrode connected to the ground potential, and a floating electrode is not provided.

FIG. 20 a graph is illustrating resonance characteristics of the acoustic wave device illustrated in FIG. 17. Examples of the design parameters of the acoustic wave device 1 including the resonance characteristics are as follows.
Piezoelectric layer 2: LiNbO₃ with Euler angles (0°, 0°, 90°)
Thickness: 400 nm
Length of region where electrodes 3 and 4 overlap as seen in direction orthogonal to length direction of electrodes 3 and 4, that is, excitation region C: 40 μm
Number of pairs of electrodes consisting of electrodes 3 and 4:21 pairs
Center-to-center distance between electrodes: 3 μm
Width of electrodes 3 and 4:500 nm
d/p: 0.133
Insulating layer 7: silicon oxide film with thickness of 1 μm
Support 8: Si

The length of the excitation region C is a dimension of the excitation region C along the length direction of the electrodes 3 and 4.

In the acoustic wave device 1, the electrode-to-electrode distances of the electrode pairs including the electrodes 3 and 4 are all equal in the plurality of pairs. That is, the electrodes 3 and the electrodes 4 are arranged with equal pitches.

As is clear from FIG. 20, good resonance characteristics with the fractional band width of about 12.5% are obtained even though no reflector is provided, for example.

As described above, in the acoustic wave device 1, d/p is less than or equal to about 0.5, more preferably less than or equal to about 0.24, for example, where d is the thickness of the piezoelectric layer 2 and p is the center-to-center distance between the electrode 3 and the electrode 4. This will be described with reference to FIG. 21.

A plurality of acoustic wave devices are obtained in the same manner as the acoustic wave device including the resonance characteristics illustrated in FIG. 20, except that d/p is changed. FIG. 21 is a graph illustrating a relationship between d/p and the fractional band width of the acoustic wave device as a resonator.

As is clear from FIG. 21, when d/p> about 0.5, the fractional band width is less than about 5% even if d/p is adjusted, for example. On the other hand, when d/p≤ about 0.5, the fractional band width can be set to more than or equal to about 5%, for example, by changing d/p within that range, that is, a resonator with a high coupling coefficient can be configured. Furthermore, when d/p is less than or equal to about 0.24, the fractional band width can be increased to more than or equal to about 7%, for example. In addition, by adjusting d/p within this range, a resonator with an even wider fractional band width can be obtained, and a resonator with an even higher coupling coefficient can be realized. Therefore, it can be seen that, by setting d/p to less than or equal to about 0.5, for example, a resonator with a high coupling coefficient can be configured using the thickness-shear mode bulk wave.

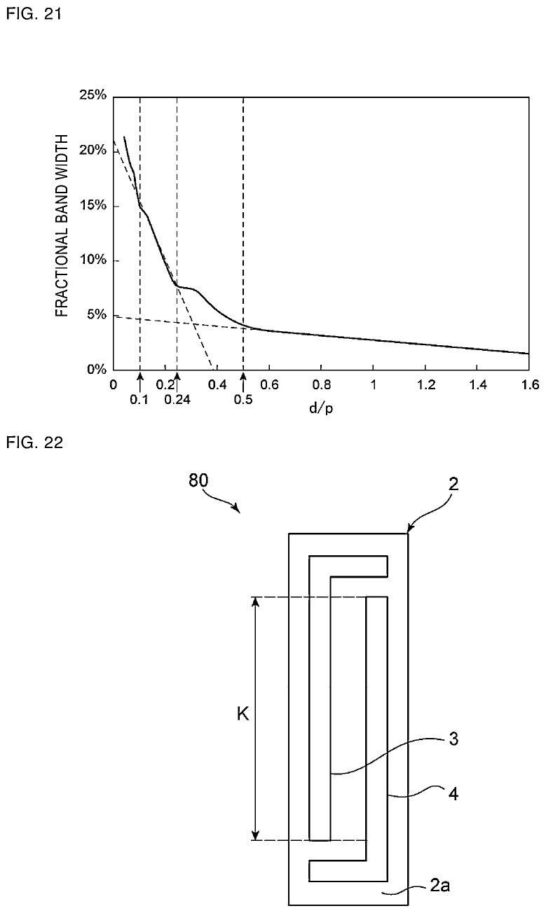

FIG. 22 is a plan view of an acoustic wave device that uses a thickness-shear mode bulk wave. In an acoustic wave device 80, a pair of electrodes, including an electrode 3 and an electrode 4, are provided on a first main surface 2a of a piezoelectric layer 2. Note that K in FIG. 22 is an intersection width. As described above, in the acoustic wave device of the present invention, the number of pairs of electrodes may be one. Even in this case, when the d/p is less than or equal to about 0.5, for example, the thickness-shear mode bulk wave can be effectively excited.

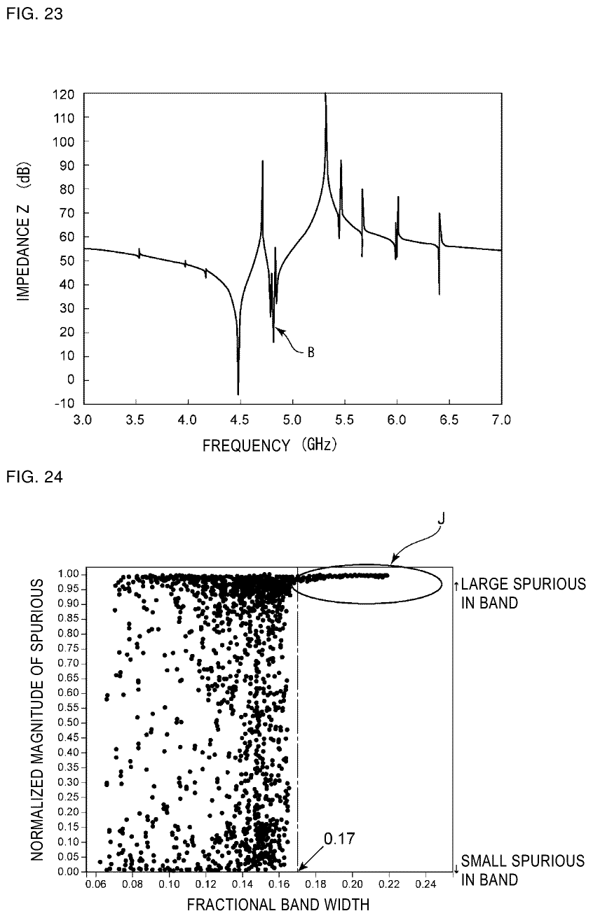

In the acoustic wave device 1, it is preferable that a metallization ratio MR of any adjacent electrodes 3 and 4 of the plurality of electrodes 3 and 4 with respect to the excitation region C, which is a region where the adjacent electrodes 3 and 4 overlap when viewed in their facing direction, satisfies MR≤ about 1.75 (d/p)+0.075, for example. In that case, spurious can be effectively reduced. This will be described with reference to FIGS. 23 and 24. FIG. 23 is a reference diagram illustrating an example of the resonance characteristics of the acoustic wave device 1. A spurious indicated by an arrow B appears between a resonant frequency and an anti-resonant frequency. Note that d/p=about 0.08 and the Euler angles of LiNbO₃ are (0°, 0°, 90°), for example. The metallization ratio MR is about 0.35, for example.

The metallization ratio MR will be described with reference to FIG. 16B. In the electrode structure of FIG. 16B, when focusing on a pair of electrodes 3 and 4, it is assumed that only this pair of electrodes 3 and 4 is provided. In this case, a portion surrounded by a dashed-dotted line is the excitation region C. When the electrode 3 and the electrode 4 are viewed in the direction orthogonal to the length direction of the electrodes 3 and 4, that is, in their facing direction, the excitation region C is a region of the electrode 3 that overlaps the electrode 4, a region of the electrode 4 that overlaps the electrode 3, and a region between the electrode 3 and the electrode 4 where the electrode 3 and the electrode 4 overlap each other. An area of the electrodes 3 and 4 in the excitation region C with respect to the area of the excitation region C is the metallization ratio MR. That is, the metallization ratio MR is the ratio of the area of the metallization portion to the area of the excitation region C.

When a plurality of pairs of electrodes are provided, the ratio of the metallization portion included in the entire excitation region to the total area of the excitation region may be MR.

FIG. 24 is a diagram illustrating a relationship between a fractional band width and a phase rotation amount of the spurious impedance normalized by 180 degrees as the magnitude of the spurious when a large number of acoustic wave resonators are configured according to the configuration of the acoustic wave device 1. The fractional band width is adjusted by changing the film thickness of the piezoelectric layer and the dimensions of the electrodes. FIG. 24 illustrates the results when a Z-cut LiNbO₃ piezoelectric layer is used, but the same tendency is obtained also when piezoelectric layers with other cut-angles are used.

In a region surrounded by an ellipse J in FIG. 24, the spurious is as large as about 1.0, for example. As is clear from FIG. 24, when the fractional band width exceeds about 0.17, that is, exceeds about 178, for example, a large spurious with a spurious level of more than or equal to about 1 appears in a pass band even when the parameters defining the fractional band width are changed. That is, as in the resonance characteristics illustrated in FIG. 23, a large spurious indicated by the arrow B appears within the band. Therefore, the fractional band width is preferably less than or equal to about 178, for example. In this case, the spurious can be reduced by adjusting the film thickness of the piezoelectric layer 2, the dimensions of the electrodes 3 and 4, or the like.

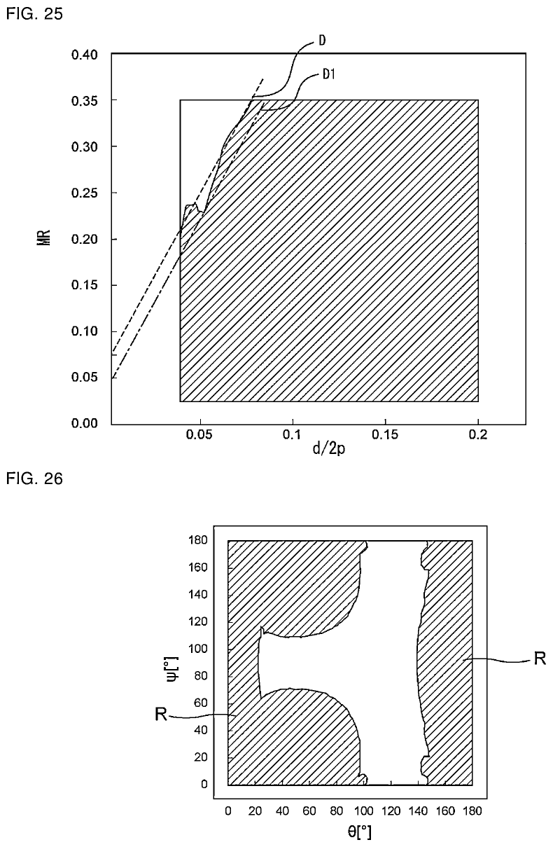

FIG. 25 is a diagram illustrating a relationship among d/2p, the metallization ratio MR, and the fractional band width. In the acoustic wave device, various acoustic wave devices including different values of d/2p and different values of MR are provided, and the fractional band width is measured. A hatched portion to the right of a dashed line D illustrated in FIG. 25 is a region where the fractional band width is less than or equal to 17%. The boundary between the hatched region and the non-hatched region is represented by MR=about 3.5 (d/2p)+0.075, for example. That is, MR=about 1.75 (d/p)+0.075, for example. Therefore, MR≤ about 1.75 (d/p)+0.075 is preferably satisfied, for example. In this case, the fractional band width is easily set to less than or equal to about 178, for example. More preferably, it is the region in FIG. 25 to the right of a dashed-dotted line D1 indicating MR=about 3.5 (d/2p)+0.05, for example. That is, when MR≤ about 1.75 (d/p)+0.05, the fractional band width can be reliably set to less than or equal to about 17%, for example.

FIG. 26 is a diagram illustrating a map of the fractional band width with respect to the Euler angles (0°, e, v) of LiNbO₃ when d/p is infinitely close to 0. A plurality of hatched regions R illustrated in FIG. 26 are regions where the fractional band width of more than or equal to about 2% is obtained, for example. When φ in the Euler angles (φ, θ, ψ) is within the range of about 0°±5°, for example, the relationship between θ and ψ and the fractional band width is the same as that illustrated in FIG. 26. Also when the piezoelectric layer is made of lithium tantalate (LiTaO₃), the relationship between θ and ψ in the Euler angles (within the range of about 0°±5°, θ, ψ) and BW is the same as that illustrated in FIG. 26.

Therefore, when φ in the Euler angles (φ, θ, ψ) of the lithium niobate or lithium tantalate of the piezoelectric layer is within the range of about 0°+5° and θ and φ are within the range of any of the regions R illustrated in FIG. 26, for example, the fractional band width can be sufficiently widened, which is preferable.

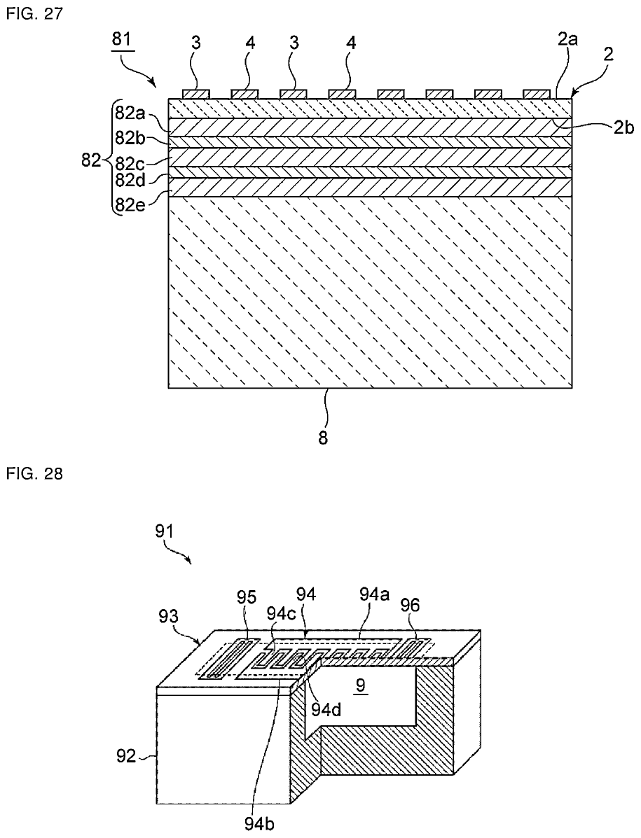

FIG. 27 is an elevational cross-sectional view of an acoustic wave device including an acoustic multilayer film.

In an acoustic wave device 81, an acoustic multilayer film 82 is laminated on a second main surface 2b of a piezoelectric layer 2. The acoustic multilayer film 82 has a multilayer structure including low acoustic impedance layers 82a, 82c, and 82e with a relatively low acoustic impedance and high acoustic impedance layers 82b and 82d with a relatively high acoustic impedance. Using the acoustic multilayer film 82 makes it possible to confine the thickness-shear mode bulk wave in the piezoelectric layer 2 without using the cavity 9 in the acoustic wave device 1. In the acoustic wave device 81, resonance characteristics based on the thickness-shear mode bulk wave can be obtained by setting the above d/p to less than or equal to about 0.5, for example. In the acoustic multilayer film 82, the number of the low acoustic impedance layers 82a, 82c, and 82e and high acoustic impedance layers 82b and 82d laminated is not particularly limited. It is sufficient that at least one high acoustic impedance layer 82b or 82d is disposed farther from the piezoelectric layer 2 than the low acoustic impedance layers 82a, 82c, and 82e.

The low acoustic impedance layers 82a, 82c, and 82e and the high acoustic impedance layers 82b and 82d can be made of any appropriate material as long as the above acoustic impedance relationship is satisfied. Examples of the material of the low acoustic impedance layers 82a, 82c, and 82e include silicon oxide or silicon oxynitride, and the like. Alumina, silicon nitride, metal or the like can be used as the material of the high acoustic impedance layers 82b and 82d.

FIG. 28 is a partially cutaway perspective view for explaining an acoustic wave device that uses a Lamb wave.

An acoustic wave device 91 includes a support substrate 92. The support substrate 92 is provided with a recessed portion that is open on its upper surface. A piezoelectric layer 93 is laminated on the support substrate 92. A cavity 9 is thus provided. An IDT electrode 94 is provided on the piezoelectric layer 93 above the cavity 9. On both sides of the IDT electrode 94 in the acoustic wave propagation direction, reflectors 95 and 96 are provided. In FIG. 28, an outer periphery of the cavity 9 is indicated by a dashed line. Here, the IDT electrode 94 includes first and second busbars 94a and 94b, a plurality of first electrode fingers 94c, and a plurality of second electrode fingers 94d. The plurality of first electrode fingers 94c are connected to the first busbar 94a. The plurality of second electrode fingers 94d are connected to the second busbar 94b. The plurality of first electrode fingers 94c and the plurality of second electrode fingers 94d are interdigitated with each other.

In the acoustic wave device 91, an AC electric field is applied to the IDT electrode 94 on the cavity 9 to excite a Lamb wave as a plate wave. Since the reflectors 95 and 96 are provided on both sides, resonance characteristics due to the Lamb wave can be obtained.

As described above, an acoustic wave device according to an example embodiment of the present invention may use the plate wave. In the example illustrated in FIG. 28, the IDT electrode 94, the reflector 95, and the reflector 96 are provided on the main surface corresponding to the first main surface 14a of the piezoelectric layer 14 illustrated in FIG. 1 and the like. On the other hand, in an acoustic wave device according to an example embodiment of the present invention, a pair of comb-shaped electrodes and a plurality of third electrode fingers are provided on the first main surface 14a. When an acoustic wave device according to an example embodiment of the present invention uses the plate wave, a pair of comb-shaped electrodes and a plurality of third electrode fingers, as well as the reflector 95 and the reflector 96 may be provided on the first main surface 14a of the piezoelectric layer 14 in the first to third example embodiments and modification. In this case, the pair of comb-shaped electrodes and the plurality of third electrode fingers may be sandwiched between the reflectors 95 and 96 in the electrode finger orthogonal direction.

In the acoustic wave devices of the first to third example embodiments and modifications, for example, the acoustic multilayer film 82 illustrated in FIG. 27 may be provided as an acoustic reflection film between the support and the piezoelectric layer. Specifically, the support and the piezoelectric layer may be arranged such that at least a portion of the support and at least a portion of the piezoelectric layer face each other across the acoustic multilayer film 82. In this case, it is sufficient that low acoustic impedance layers and high acoustic impedance layers are alternately laminated in the acoustic multilayer film 82. The acoustic multilayer film 82 may be an acoustic reflection portion in the acoustic wave device.

In the acoustic wave devices according to the first to third example embodiments and modifications that use the thickness-shear mode bulk wave, as described above, d/p is preferably less than or equal to about 0.5, and more preferably less than or equal to about 0.24, for example. This makes it possible to obtain even better resonance characteristics.

Furthermore, in the excitation region of the acoustic wave devices according to the first to third example embodiments and modifications that use the thickness-shear mode bulk wave, as described above, MR≤ about 1.75 (d/p)+0.075 is preferably satisfied, for example. More specifically, MR≤ about 1.75 (d/p)+0.075 is preferably satisfied, for example, where MR is the metallization ratio of the first and third electrode fingers and the second and third electrode fingers to the excitation region. In this case, spurious can be more reliably suppressed.

While example embodiments of the present invention have been described above, it is to be understood that variations and modifications will be apparent to those skilled in the art without departing from the scope and spirit of the present invention. The scope of the present invention, therefore, is to be determined solely by the following claims.

What is claimed is:

1. An acoustic wave device comprising:
a piezoelectric substrate including a piezoelectric layer including a first main surface and a second main surface that face each other, and a support laminated on the second main surface of the piezoelectric layer;
a first comb-shaped electrode that is provided on the first main surface of the piezoelectric layer, includes a first busbar and a plurality of first electrode fingers each including one end connected to the first busbar, and is connected to an input potential;
a second comb-shaped electrode that is provided on the first main surface of the piezoelectric layer, includes a second busbar and a plurality of second electrode fingers each including one end connected to the second busbar and interdigitated with the plurality of first electrode fingers, and is connected to an output potential; and
a reference potential electrode that is connected to a reference potential and includes a plurality of third electrode fingers provided on the first main surface of the piezoelectric layer so as to be aligned with the first electrode fingers and the second electrode fingers in a direction in which the first electrode fingers and the second electrode fingers are arranged, a plurality of connection electrodes connected to the plurality of third electrode fingers, respectively, and a third busbar electrically connected to the plurality of third electrode fingers by the plurality of connection electrodes; wherein
an order in which the first electrode finger, the second electrode finger, and the third electrode finger are arranged is such that, starting from the first electrode finger, the first electrode finger, the third electrode finger, the second electrode finger, and the third electrode finger define one period; and
the third busbar faces the plurality of third electrode fingers across at least the piezoelectric layer, and the plurality of connection electrodes penetrate at least the piezoelectric layer to connect the third busbar to the plurality of third electrode fingers.

2. The acoustic wave device according to claim 1, wherein the third busbar is provided on the second main surface of the piezoelectric layer.

3. The acoustic wave device according to claim 2, wherein the support includes an insulating layer provided on the second main surface of the piezoelectric layer so as to cover the third busbar.

4. An acoustic wave device comprising:
a piezoelectric substrate including a piezoelectric layer including a first main surface and a second main surface that face each other;
a first comb-shaped electrode that is provided on the first main surface of the piezoelectric layer, includes a first busbar and a plurality of first electrode fingers each including one end connected to the first busbar, and is connected to an input potential;
a second comb-shaped electrode that is provided on the first main surface of the piezoelectric layer, includes a second busbar and a plurality of second electrode fingers each including one end connected to the second busbar and interdigitated with the plurality of first electrode fingers, and is connected to an output potential;
a reference potential electrode that is connected to a reference potential and includes a plurality of third electrode fingers provided on the first main surface of the piezoelectric layer so as to be aligned with the first electrode fingers and the second electrode fingers in a direction in which the first electrode fingers and the second electrode fingers are arranged, a plurality of connection electrodes connected to the plurality of third electrode fingers, respectively, and a third busbar electrically connected to the plurality of third electrode fingers by the plurality of connection electrodes;
a support provided on the piezoelectric substrate; and
a cover that is provided on the support and includes a third main surface located on the piezoelectric substrate side and a fourth main surface facing the third main surface; wherein
an order in which the first electrode finger, the second electrode finger, and the third electrode finger are arranged is such that, starting from the first electrode finger, the first electrode finger, the third electrode finger, the second electrode finger, and the third electrode finger define one period; and
the third busbar is provided on the third main surface of the cover so as to face the plurality of third electrode fingers, and the plurality of connection electrodes are provided at least on the plurality of third electrode fingers, and connect the third busbar to the plurality of third electrode fingers.

5. The acoustic wave device according to claim 4, wherein at least one of the connection electrodes is provided on the third electrode finger and on the piezoelectric layer.

6. The acoustic wave device according to claim 4, wherein the cover includes a silicon substrate.

7. An acoustic wave device comprising:
a piezoelectric substrate including a piezoelectric layer including a first main surface and a second main surface that face each other;
a first comb-shaped electrode that is provided on the first main surface of the piezoelectric layer, includes a first busbar and a plurality of first electrode fingers each including one end connected to the first busbar, and is connected to an input potential;
a second comb-shaped electrode that is provided on the first main surface of the piezoelectric layer, includes a second busbar and a plurality of second electrode fingers each including one end connected to the second busbar and interdigitated with the plurality of first electrode fingers, and is connected to an output potential;
a reference potential electrode that is connected to a reference potential and includes a plurality of third electrode fingers provided on the first main surface of the piezoelectric layer so as to be aligned with the first electrode fingers and the second electrode fingers in a direction in which the first electrode fingers and the second electrode fingers are arranged, a plurality of connection electrodes connected to the plurality of third electrode fingers, respectively, and a third busbar electrically connected to the plurality of third electrode fingers by the plurality of connection electrodes;
a plurality of conductive bonds provided on the piezoelectric substrate; and
a mounting substrate that is bonded to the piezoelectric substrate by the plurality of conductive bonds, and includes a fifth main surface located on the piezoelectric substrate side and a sixth main surface facing the fifth main surface; wherein
an order in which the first electrode finger, the second electrode finger, and the third electrode finger are arranged is such that, starting from the first electrode finger, the first electrode finger, the third electrode finger, the second electrode finger, and the third electrode finger define one period; and
the third busbar is provided on the fifth main surface of the mounting substrate so as to face the plurality of third electrode fingers, and the plurality of connection electrodes are provided at least on the plurality of third electrode fingers, and connect the third busbar to the plurality of third electrode fingers.

8. The acoustic wave device according to claim 7, wherein a sealing resin is provided on the fifth main surface of the mounting substrate so as to cover the piezoelectric substrate and to define a hollow portion together with the piezoelectric substrate and the mounting substrate.

9. The acoustic wave device according to claim 7, wherein the plurality of conductive bonds include a plurality of bumps.

10. The acoustic wave device according to claim 1, wherein the piezoelectric substrate includes a support substrate laminated with the piezoelectric layer.

11. The acoustic wave device according to claim 1, wherein the acoustic wave device is structured to generate a plate wave.

12. The acoustic wave device according to claim 1, wherein the acoustic wave device is structured to generate a thickness-shear mode bulk wave.

13. The acoustic wave device according to claim 1, wherein
the piezoelectric substrate includes a support laminated on the second main surface of the piezoelectric layer;
an acoustic reflection portion is provided at a position on the support that overlaps with the plurality of first electrode fingers, the plurality of second electrode fingers, and the plurality of third electrode fingers in plan view along a lamination direction of the support and the piezoelectric layer; and
d/p is less than or equal to about 0.5, where p is a longest distance of a center-to-center distance between the first electrode finger and the third electrode finger adjacent to each other and a center-to-center distance between the second electrode finger and the third electrode finger adjacent to each other, and d is a thickness of the piezoelectric layer.

14. The acoustic wave device according to claim 13, wherein d/p is less than or equal to about 0.24.

15. The acoustic wave device according to claim 13, wherein the acoustic reflection portion is a cavity, and the support and the piezoelectric layer are arranged such that a portion of the support and a portion of the piezoelectric layer face each other across the cavity.

16. The acoustic wave device according to claim 13, wherein the acoustic reflection portion includes an acoustic reflection film including a high acoustic impedance layer with a relatively high acoustic impedance and a low acoustic impedance layer with a relatively low acoustic impedance, and the support and the piezoelectric layer are arranged such that at least a portion of the support and at least a portion of the piezoelectric layer face each other across the acoustic reflection film.

17. The acoustic wave device according to claim 13, wherein
an excitation region is a region where the first electrode finger and the third electrode finger adjacent to each other overlap each other in an electrode finger orthogonal direction that is a direction orthogonal to a direction in which the first electrode finger, the second electrode finger, and the third electrode finger extend, and a region where the second electrode finger and the third electrode finger adjacent to each other overlap each other in the electrode finger orthogonal direction; and
MR≤ about 1.75 (d/p)+0.075 is satisfied, where MR is a metallization ratio of the first electrode finger and the third electrode finger, and the second electrode finger and the third electrode finger to the excitation region.

18. The acoustic wave device according to claim 1, wherein the piezoelectric layer is made of lithium tantalate or lithium niobate.

19. The acoustic wave device according to claim 18, wherein
Euler angles (φ, θ, ψ) of the lithium niobate or lithium tantalate included in the piezoelectric layer are within the range of Expression (1), Expression (2), or Expression (3):
(within the range of 0°±10°,0° to 25°, any ψ) Expression (1)
(within the range of 0°±10°,25° to 100°,75°[(1−(θ−50)²/2500)]^{1/2} or 180°−75°[(1−(θ−50)²/2500)]^{1/2} to 180°) Expression (2)
(within the range of 0°±10°,180°−40°[(1−(ψ−90)²/8100)]^{1/2} to 180°, any ψ) Expression (3).

20. The acoustic wave device according to claim 7, wherein the acoustic wave device is structured to generate a plate wave or a thickness-shear mode bulk wave.
